(19) United States
(12) Patent Application Publication
(10) Pub. No.: US 2018/0318968 A1
(43) Pub. Date: Nov. 8, 2018

(54) Solder for Limiting Substrate Damage Due to Discrete Failure

(71) Applicant: International Business Machines Corporation, Armonk, NY (US)

(72) Inventors: Bruce J. Chamberlin, Vestal, NY (US); Scott B. King, Rochester, MN (US); Joseph Kuczynski, North Port, FL (US); David J. Russell, Owego, NY (US)

(73) Assignee: International Business Machines Corporation, Armonk, NY (US)

(21) Appl. No.: 15/589,130

(22) Filed: May 8, 2017

(51) Int. Cl. B23K 35/362; H05K 3/34; B23K 35/02; B23K 35/26; B23K 35/28; B23K 35/30; B23K 35/36

(52) U.S. Cl. CPC B23K 35/362; H05K 3/3463; B23K 35/0227; B23K 35/025; B23K 35/268; B23K 35/262; B23K 2201/42; B23K 35/3006; B23K 35/302; B23K 35/3026; B23K 35/3618; B23K 35/3615; H05K 2203/176; B23K 35/282

(57) ABSTRACT

A solder composition comprising a material in a first phase (e.g., liquid and/or solid phase) with a transition temperature is provided. Exposure of the solder to a temperature that meets or exceeds the transition temperature causes the material to undergo a phase change from the first phase to a gaseous phase. The phase change physically transforms the solder material.

### BACKGROUND

The present embodiments relate generally to mitigating damage to a substrate. More specifically, the embodiments relate to solder to facilitate separation of a failing component from the substrate prior to the substrate and/or failing component experiencing damage.

The substrate is configured to support electronics and/or electrical energy. An example of the substrate comprised of a conducting material includes, but is not limited to, a printed circuit board (PCB). The conducting material is utilized to electronically connect components operatively coupled to the substrate, such as resistors, capacitors, and other devices. Exposure of the substrate to damage may require replacement of the substrate. Similarly, exposure of one or more of the connected components to damage may require replacement of the affected component(s), one or more proximally positioned components, and/or in some circumstances the substrate.

It is understood that a discrete component in communication with the substrate may experience a failure, such as an electrical short which causes excess current to be driven through the discrete component and/or the substrate. Excess current leads to resistive heating and subsequent thermal runaway leading to smoke, fire, failure of the component, failure of a PCB trace, failure of the PCB, and/or damage to the surrounding devices.

### SUMMARY

The disclosed embodiments pertain to mitigating potential damage to a discrete component and/or a proximally positioned substrate by utilizing solder to separate a failing component from the substrate prior to the substrate experiencing damage.

In one aspect, a composition is provided which comprises 1 to 5 weight percent of a first material in a first phase having a transition temperature above a liquidus temperature of a solder material. The balance of the composition is the solder material. Responsive to exposure of the first material to a thermal event of at least the transition temperature, the first material is subjected to a phase change from the first phase to a second phase. The phase change physically transforms the solder material.

In another aspect, a solder joint to attach a component to a substrate is provided. The solder joint composition comprises 1 to 5 weight percent of a first material in a first phase having a transition temperature above a liquidus temperature of a solder material. The balance of the composition is the solder material. Responsive to exposure of the first material to a thermal event of at least the transition temperature, the first material is subjected to a phase change from the first phase to a second phase. The phase change physically transforms the solder material including an expansion of the first material. The expansion interrupts the solder joint, with the interruption including a separation of the component from the substrate.

These and other features and advantages will become apparent from the following detailed description of the presently preferred embodiment(s), taken in conjunction with the accompanying drawings.

### BRIEF DESCRIPTION OF THE SEVERAL VIEWS OF THE DRAWINGS

The drawings referenced herein form a part of the specification. Features shown in the drawings are meant as illustrative of only some embodiments, and not of all embodiments, unless otherwise explicitly indicated.

FIG. 1 depicts a block diagram illustrating positioning of discrete components to the substrate together with the solder.

FIG. 2 depicts a block diagram illustrating separation of the component from the substrate upon exposure of the solder to a thermal event.

FIG. 3 depicts a flow chart illustrating a process for mitigating damage to the substrate upon exposure to a thermal event.

### DETAILED DESCRIPTION

It will be readily understood that the components of the present embodiments, as generally described and illustrated in the Figures herein, may be arranged and designed in a wide variety of different configurations. Thus, the following detailed description of the embodiments of the apparatus, system, and method of the present embodiments, as presented in the Figures, is not intended to limit the scope of the embodiments, as claimed, but is merely representative of selected embodiments.

Reference throughout this specification to “a select embodiment,” “one embodiment,” or “an embodiment” means that a particular feature, structure, or characteristic described in connection with the embodiment is included in at least one embodiment of the present embodiments. Thus, appearances of the phrases “a select embodiment,” “in one embodiment,” or “in an embodiment” in various places throughout this specification are not necessarily referring to the same embodiment.

The illustrated embodiments will be best understood by reference to the drawings, wherein like parts are designated by like numerals throughout. The following description is intended only by way of example, and simply illustrates certain selected embodiments of devices, systems, and processes that are consistent with the embodiments as claimed herein.

Unless the meaning is clearly to the contrary, all references made herein to ranges are to be understood as inclusive of the endpoints of the ranges. The modifier “about” used in connection with a quantity is inclusive of the stated value and has the meaning dictated by the context (e.g., includes the degree of error associated with measurement of the particular quantity). Unless the meaning is clearly to the contrary, all references made herein to pressures, such as psi, are to be understood as relative to atmospheric pressure.

Exposure of a substrate and/or a component positioned proximal to the substrate to a critical temperature can cause damage to the substrate and/or the component. Effects of the exposure may include, but are not limited to, fire, smoke, spark, functionality loss, and/or deformation. In one embodiment, the component(s) and the substrate may have a critical temperature, with exposure to the critical temperature leading to damage. Examples of the critical temperature include, but are not limited to, exposure above about 1000 degrees Celsius and exposure above about 500 degrees Celsius. Different components comprised of different materials may have separate and unique critical temperatures. For example, component₀ may have a first critical temperature, temperature₀, and component₁ may have a second critical temperature, temperature₁, with temperature₀ and temperature₁ being different. Similarly, a substrate in communication with both component₀ and component₁ may have a third critical temperature, temperature₂, different from temperature₀ and temperature₁. In one embodiment, at least one of the components or substrate may have a matching critical temperature. In one embodiment, individual components in communication with the substrate may have separate critical temperatures. Similarly, in one embodiment, the critical temperature of the substrate may be separate from the critical temperature(s) of the components in communication with the substrate. In one embodiment, the critical temperature may be selected from a lowest critical temperature of each of the components and the substrate. Accordingly, the critical temperature is a characteristic of the component(s) and/or substrate at which they are subject to failure.

A temperature increase on the substrate and/or component(s) may be caused by a variety of different factors, including but not limited to a high current event and/or an electrical short. High current through a conductor on the substrate or in one of the components in communication with the substrate can lead to resistive heating causing temperature increases in the substrate and thermal runaway. For example, the thermal runaway may be an increase in temperature of the conductor experiencing the high current which leads to an increase in resistance of the conductor which causes further increases in temperatures.

The electrical short may be caused by, but is not limited to, a component operatively coupled to the substrate, solder bridging, and/or a component shift. The component operatively coupled to the substrate may have a short (e.g., lower resistance) leading to excessive heating within the component and resultant thermal runaway. Solder bridging occurs when solder connects two conductors which were not designed to be connected together and causes a lower resistance path (e.g., an electrical short) for an electrical circuit. The component shift is when the component is misaligned with the electrical interface on the substrate due to movement of the component. For example, the component may shift from a first position to a second position during a solder reflow process. Accordingly, either an electrical short or a high current event can lead to damage of the substrate and/or component operatively coupled to the substrate.

Damage (e.g., burns) to the substrate and/or operatively coupled component includes, but is not limited to, smoke, fire, failure of the component, failure of a portion of the substrate, failure of the entire substrate, and/or damage to surrounding devices. In one embodiment, damage may be caused by a discrete failure of a single component, and the substrate may continue to function without the failing component. Accordingly, if the failure of a failing component can be managed or otherwise isolated prior to causing damage to the substrate and/or other component(s), the damage caused by the failure is limited, or in one embodiment isolated, and the substrate may remain operational and/or repairable.

Solutions to limit damage to the substrate due to a discrete failure are provided, with embodiments directed at a composition and apparatus as discussed below in detail. As shown and described, the apparatus includes a solder employed to operatively bond a component to a substrate. It is understood in the art that an electrical component, such as a capacitor, resistor, etc., is mechanically and electrically coupled to the substrate, such as a printed circuit board (PCB). The solder is configured with a material in a first phase (e.g., solid and/or liquid phase) with a transition temperature above a liquidus temperature of the solder. In one embodiment, the solder is configured with a material in a first phase with a transition temperature above the reflow temperature of an assembly of the component and the substrate. The transition temperature is a temperature, or in one embodiment, a temperature range at which the material in the first phase will phase change to a gaseous phase.

Exposure of the solder to a thermal event that meets or exceeds the transition temperature of the material causes the material to undergo the phase change from the first phase to a gaseous phase including a physical transformation of the solder. In one embodiment, the thermal event is an increase in temperature that meets or exceeds the transition temperature caused by an electrical short. In one embodiment, the electrical short is in the component. The phase change alters a physical position of the component in relation to the substrate. More specifically, prior to the phase change, the component is in a first position in relation to the substrate, and after the phase change, the component is in a second position in relation to the substrate. In the first position, the component is mechanically and/or electrically coupled to the substrate; in the second position, the component is mechanically and/or electrically separated from the substrate. Separation of the component from the substrate in the second position may be a partial separation or a complete separation. Regardless of the quantity of separation, there is a disruption of the flow of electrical energy (e.g., decrease in current) between the component and the substrate, with the disruption mitigating additional temperature increase of the component and/or substrate. In one embodiment, the disruption limits damage to the discrete component and/or localized area. In one embodiment, the second position is an indication that the component has experienced a failure, thereby facilitating the process of locating and/or identifying the failing component. Accordingly, integration of the solder with the component and the substrate mitigates damage to the substrate and/or component responsive to the thermal event.

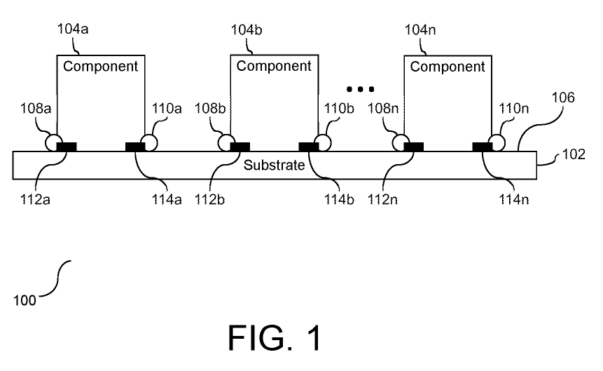

Referring to FIG. 1, a block diagram (100) is provided illustrating positioning of discrete components to the substrate together with the solder. As described in detail below, the configuration functions to limit damage to an associated substrate responsive to exposure of the solder to a thermal event. As shown, a plurality of components (104a), (104b), and (104n), is adjacently positioned across a substrate (102), e.g. mechanically and electrically coupled to the substrate. As shown, each of the components (104a)-(104n) is in a first position relative to the substrate (102). The components may be, but are not limited to, a resistor, a capacitor, an optoelectronic device, an oscillator, a connector, a potentiometer, an integrated circuit, a sensor, a transducer, a relay, a switch, a driver, a motor, a power supply, a transformer, and similar devices. Each component (104a)-(104n) may be the same type of component or different types of components. The quantity of component(s), and substrate(s) is for illustration purposes only and should not be considered limiting. Accordingly, a plurality of components are provided on the external surface (106) of substrate (102).

As shown, contacts are provided for each component (104a)-(104n) to support securing the component to the substrate (102) together with enabling electrical communication with the substrate (102). More specifically, component (104a) includes contacts (112a) and (114a), component (104b) includes contacts (112b) and (114b), and component (104n) includes contacts (112n) and (114n). Each of the contacts (112a)-(112n) and (114a)-(114n) are positioned on the external surface (106) of the substrate (102). Furthermore, as shown herein, each of the contacts (112a)-(112n) and (114a)-(114n) are in a first position relative to the substrate (102). The quantity of contact(s) is for illustration purposes and should not be considered limiting. Accordingly, prior to exposure to a thermal event, each component (104a)-(104n) is electrically and mechanically provided in a first position and in communication with the substrate (102).

The substrate (102) may be, but is not limited to, a printed circuit board (PCB), an interposer, and a motherboard. The component contacts (112a)-(112n) may be operatively coupled to the substrate (102) by solder joints (108a)-(108n), respectively. In one embodiment, component contacts (114a)-(114n) may be operatively coupled to substrate (102) by solder joints (110a)-(110n), respectively. In one embodiment, components (104a)-(104n) are attached to substrate (102) by a solder reflow process. Accordingly, the components (104a)-(104n) are operatively coupled to the substrate (102) by solder joints (108a)-(108n) utilizing a solder reflow process.

During the solder reflow process, a solder comprising a material with a transition temperature is placed on the external surface (106) of the substrate (102). The solder is placed at one or more designated locations (e.g. electrical interface pattern) on the substrate (102) to which the contacts (112a)-(112n) and (114a)-(114n) of the components (104a)-(104n) are to be attached to the substrate (102). The components (104a)-(104n) are placed in communication with, e.g. onto, the substrate (102) with solder residing between component contacts (112a)-(112n) and (114a)-(114n) and the electrical interface pattern on the external surface (106) of the substrate (102). An assembly of the substrate (102) and components (104a)-(104n) is subject to a heating process where the assembly encounters a profile of a rising or increased temperature, that in one embodiment reaches a peak temperature above the solder reflow temperature (e.g. liquidus temperature of the solder). At the peak temperature, the solder is subject to a softening, or in one embodiment, melting, and an electrical connection between the components (104a)-(104n) and the electrical interface pattern may be established. In one embodiment, the peak temperature is below the transition temperature of the material to prevent premature degradation of the material (e.g. changes in phase) in solder joints (108a)-(108n) and (110a)-(110n).

The solder reflow process is concluded with a cool down period where the solder changes to a solid phase (e.g. below the liquidus temperature of the solder) to form one or more solder joints (108a)-(108n) and (110a)-(110n) (e.g. physical and electrical connections). In one embodiment, the liquidus temperature is less than about 200 degrees Celsius. The solder may be, but is not limited to, leaded solder, lead free solder, solder paste, solder wire, and conductive adhesives. In one embodiment, solder joints (108a)-(108n) and (110a)-(110n) form an electrical and/or mechanical connection between the components (104a)-(104n) and the substrate (102). In one embodiment, the first temperature is the liquidus temperature of solder in at least one of the solder joints (108a)-(108n) and (110a)-(110n). Accordingly, the solder joints (108a)-(108n) and (110a)-(110n) may electrically and mechanically attach the components (104a)-(104n) to the substrate (102).

Each solder joint (108a)-(108n) and (110a)-(110n) is configured to physically transform upon exposure to a transition temperature of a material. In one embodiment, the transition temperature is above a first temperature and below a critical temperature. Exposure of the substrate (102) to a critical temperature may cause damage to the substrate (102). The first temperature is defined as a temperature at which a physical attachment due to solder joints (108a)-(108n) and (110a)-(110n) between the component (104a) and the substrate (102) is mechanically weakened, as described in detail below. Accordingly, in this example each component (104a)-(104n) is shown operatively coupled to substrate (102) by solder joints (108a)-(108n) and (110a)-(110n).

Each solder joint (108a)-(108n) and (110a)-(110n) is configured with a material in a first phase (e.g., solid phase or liquid phase) having a transition temperature. The material may be, but is not limited to, phthalic anhydride, terephthalic acid, and adamantine. In one embodiment, the solder comprises about 0.5 to about 15 weight percent of the material, and in one embodiment, about 1 to about 10 weight percent of the material, and the balance is one or more solder components. In one embodiment, the solder comprises about 1 to about 5 weight percent of the material and the balance is one or more solder components. The solder component may be, but is not limited to, tin, silver, lead, copper, zinc, manganese, and indium. In one embodiment, the solder is composed of 1 to 5 weight percent of the material and the balance of the solder being tin and lead in a 63 weight percent tin and 37 weight percent lead ratio and has a reflow temperature of 183 degrees Celsius. In one embodiment, the transition temperature is above about 270 degrees Celsius and below about 500 degrees Celsius. The transition temperature may be, but is not limited to, an evaporation temperature, and a sublimation temperature. For example, phthalic anhydride has a sublimation temperature of 295 degree Celsius, terephthalic acid has a sublimation temperature of 402 degrees Celsius, and adamantine has a sublimation temperature of 270 degrees Celsius. In one embodiment, the sublimation temperature of the material can withstand the solder reflow operation without premature decomposition of the material. In one embodiment, the transition temperature, the sublimation temperature, the evaporation temperature, the critical temperature, and the first temperature are measured at one atmosphere of absolute pressure.

In one embodiment, each solder joint (108a)-(108n) and (110a)-(110n) may be configured with a distinct material composition. For example, the material composition may be selected based on a property of the component. Similarly, in one embodiment, the material composition may be selected based on a property of the substrate, or based on a combination of the property of the component and the substrate. In one embodiment, the solder comprises 1 to 10 weight percent of one or more of the following, but not limited to, the reaction product of hexamethyldisilazane with silica, methyltrimethoxysilane, octamethylcyclotetrasiloxane, methanol, phthalic anhydride, polydimethylsiloxane, and silica filler. Accordingly, the solder joints (108a)-(108n) and (110a)-(110n) comprise a material configured to undergo a phase change before the substrate (102) is exposed to a critical temperature.

Referring to FIG. 1, the solder joints (108a)-(108n) and (110a)-(110n) are at an operating temperature and the material within solder joints (108a)-(108n) and (110a)-(110n) is in a first phase (e.g., solid and/or liquid phase). The operating temperature is a temperature at which the electrical circuit formed between each component (104a)-(104n) and the substrate (102) is functional. The operating temperature may be a temperature below about 150 degrees Celsius. The substrate (102) may experience damage if the substrate (102) is exposed to a critical temperature. For example, a critical temperature may be caused by a high current event and/or an electrical short in the substrate (102) and/or the components (104a)-(104n). In order to mitigate potential damage to the substrate (102), the material in the solder joints (108a)-(108n) and (110a)-(110n) is configured to undergo a phase change (e.g. transition process) prior to reaching a critical temperature.

For example, in one embodiment, component (104a) experiences an electrical short while components (104b)-(104n) are not or have not experienced an electrical short. If the electrical short causes the substrate (102) to reach a critical temperature, the functionality and/or physical characteristics of the substrate (102) and/or components (104a)-(104n) may be affected. However, if the discrete failing component (104a) is separated from the substrate (102) before a critical temperature is reached, the substrate (102) may not be affected by the thermal event caused by the electrical short of component (104a) and as such the substrate (102) and components (104b)-(104n) may continue to operate without component (104a). In one embodiment, (104b) is a backup component for (104a). In one embodiment, components (104a) and (104b) are different components. Separation of an individual component, such as component (104a) is referred to herein as discrete removal, which effectively limits removal to an individual component. Accordingly, discrete removal of component (104a) mitigates potential damage to the substrate (102) and/or non-failing components (104b)-(104n).

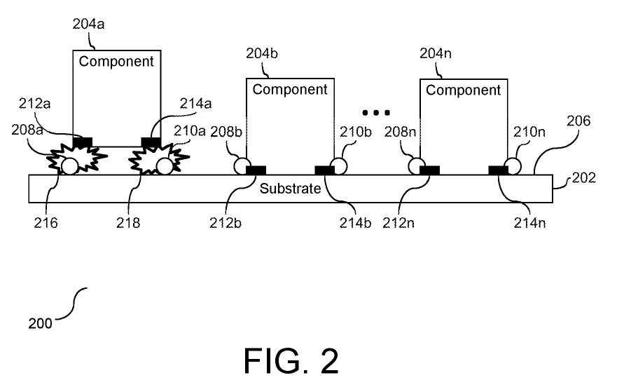

Referring to FIG. 2, a block diagram (200) is provided illustrating separation of a component from the substrate upon exposure of the solder to a thermal event. As shown, the electrical short in component (204a) has exposed solder joints (208a) and (210a) to a thermal event. The thermal event causes the temperature of solder joints (208a) and (210a) to increase from the operating temperature to a second temperature above the liquidus temperature of the solder component in solder joints (208a) and (210a). This increase of the temperature causes a softening and/or melting of solder joints (208a) and (210a) to where the physical attachment between the component (204a) and the substrate (202) is weakened. Additionally, the second temperature meets or exceeds the transition temperature of the material. Exposure of the solder joints (208a) and (210a) to the thermal event causes the solder joints (208a) and (210a) to undergo a physical transformation, including changing the material from the solid phase to a gaseous phase (e.g. sublimation). In one embodiment, the material is changed from a liquid phase to a gaseous phase (e.g. evaporation). The phase change transforms the physical configuration of the solder joints (208a) and (210a) including a rapid expansion of the material creating expanded volumes (216) and (218) of the gaseous material. Accordingly, subjecting the material to the thermal event causes the material to transition from the first phase to the gaseous phase.

Due to the weakened physical attachment of the component to the substrate, at least one of the expanded volumes (216) and (218) alters the position of the component (204a). This altered position is also referred to herein as a second position, which separates component (204a) from the external surface (206) of substrate (202). In one embodiment, the volumes (216) and (218) create an area of pressure which separates the component (204a) from the external surface (206) of substrate (202). The separation includes an interruption of at least one of solder joints (208a) and (210a). This interruption is an electrical disruption of the electrical connection, and in one embodiment a mechanical disconnect, between the component (204a) and substrate (202). The separation is caused by a force associated with the volume expansion of the material. The disruption of the electrical connection caused by the force mitigates the electrical short in the component (204a), which limits any further temperature increases to the substrate (202) and/or component (204a) caused by the electrical short. In one embodiment, the solder joints (208a) and (210a) remain physically transformed even after cooling below the transition temperature. Accordingly, the material discretely separates the component experiencing the thermal event from the substrate in order to mitigate and/or localize potential damage.

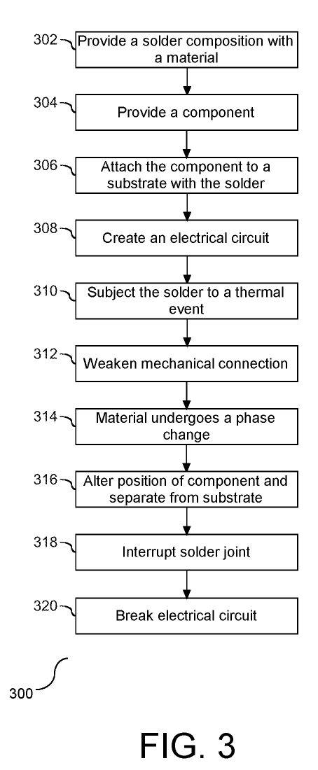

Referring to FIG. 3, a flow chart (300) is provided illustrating a process for mitigating damage to a substrate and/or component upon exposure to a thermal event. As shown, a solder is provided with at least one material in a first phase (e.g., solid and/or liquid phase) with a transition temperature (302). In one embodiment, the transition temperature is above a first temperature and less than a critical temperature that will cause damage to a substrate and/or a component. The first temperature is a temperature which weakens a mechanical attachment between the component and the substrate. In one embodiment, the first temperature is the liquidus temperature of the solder. In one embodiment, the first temperature is the reflow temperature of an assembly of the component and the substrate. The material is configured to phase change, e.g. from the first phase to gaseous phase, in response to exposure of the solder to a temperature of at least the transition temperature. The component is provided and prepared to be configured with the substrate (304). Following configuration of the component at step (304), the component is operatively coupled to the substrate in a first position with the solder, and in one embodiment, at least a portion of the solder is positioned between contacts of the component and the substrate (306). In one embodiment, step (306) includes a solder reflow process and the forming of a solder joint between the component and the substrate. Formation of the solder joint includes creating an electrical connection between the substrate and the component (308). In one embodiment, the solder joint creates a mechanical attachment between the component and the substrate. Accordingly, following step (306) the substrate and component are mechanically attached and an electrical circuit created between the substrate and the component is operational.

The solder is subjected to a thermal event that meets or exceeds the transition temperature of the material (310). The thermal event may be caused by an electrical short in the component and/or substrate. Responsive to the thermal event, the mechanical connection between the component and the substrate is weakened (312). In one embodiment, the weakened connection may include a softening and/or melting of the solder joint (312). The material within the solder is subjected to a phase change that includes changing the material from the first phase (e.g. solid and/or liquid phase) to a gaseous phase (314). The phase change transforms the physical configuration of the solder and creates a rapid volume expansion of the material which alters a position of the component from the first position to a second position, including separating the component from the substrate (316). This separation interrupts the solder joint (318) and breaks the electrical circuit formed between the component and the substrate. In addition, the solder joint separation causes the electrical circuit to be non-operational (320). More specifically, the disruption of the electrical communications between the substrate and the component limits further temperature increases to the substrate and/or component which may cause damage to the affected component, other components, and/or substrate. Accordingly, the solder is configured with a material which enables discrete separation of the component from the substrate in order to isolate damage caused by the electrical short.

The terminology used herein is for the purpose of describing particular embodiments only and is not intended to be limiting of the embodiments. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present embodiments has been presented for purposes of illustration and description, but is not intended to be exhaustive or limited to the embodiments in the form disclosed.

The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments. The embodiments were chosen and described in order to best explain the principles of the embodiments and the practical application, and to enable others of ordinary skill in the art to understand the embodiments for various embodiments with various modifications as are suited to the particular use contemplated. Accordingly, the implementation of solder with a material configured to undergo a transition process can be used to limit damage to a discrete component of a substrate.

It will be appreciated that, although specific embodiments have been described herein for purposes of illustration, various modifications may be made without departing from the spirit and scope of the embodiments. In particular, any type of components may be used in association with the spirit and scope of the embodiments. The component may be, but is not limited to, an electrical device, a socket, and or a mechanical attachment between a secondary body and a substrate. Additionally, the embodiments may apply to non-electronic components which are heat sensitive and positioned in communication with or operatively coupled to a substrate. Accordingly, the scope of protection of the embodiments is limited only by the following claims and their equivalents.

1. A composition comprising:
about 0.5 to about 15 weight percent of a first material in a first phase having a transition temperature above a liquidus temperature of a solder material;
balance of the solder material;
responsive to exposure of the first material to a thermal event of at least the transition temperature, the first material subject to a phase change from the first phase to a second phase; and
the phase change to physically transform the solder material.

2. The composition of claim 1, wherein the first material is selected from the group consisting of: phthalic anhydride, terephthalic acid, and adamantine.

3. The composition of claim 2, wherein the solder material further comprises at least one second material selected from the group consisting of: tin, silver, lead, copper, zinc, manganese, and indium.

4. The composition of claim 3, wherein the liquidus temperature is less than about 200 degrees Celsius.

5. The composition of claim 4, wherein the solder material is in a state selected from the group consisting of: a paste and a wire.

6. The composition of claim 4, further comprising 1 to 10 weight percent of at least one third material selected from the group consisting of: a reaction product of hexamethyldisilazane with silica, methyltrimethoxysilane, octamethylcyclotetrasiloxane, methanol, polydimethylsiloxane, and silica.

7. The composition of claim 6, wherein the transition temperature of the first material is above about 270 degrees Celsius and less than about 500 degrees Celsius.

8. The composition of claim 7, wherein the physical transformation creates an area of pressure based on a volume expansion of the first material.

9. (canceled)

10. (canceled)

11. (canceled)

12. (canceled)

13. (canceled)

14. (canceled)

15. (canceled)

16. (canceled)

17. (canceled)
